(19) United States
(12) Patent Application Publication
(10) Pub. No.: US 2026/0143283 A1
(43) Pub. Date: May 21, 2026

(54) SYSTEMS AND METHODS FOR WORKSITE AUDIO DEVICE WITH AUTOMATIC VOLUME CONTROL

(71) Applicant: Milwaukee Electric Tool Corporation, Brookfield, WI (US)

(72) Inventors: Steven K. Hansen, Port Washington, WI (US); Alvin N. Thou, Milwaukee, WI (US); Gregory R. Strommen, Brookfield, WI (US)

(21) Appl. No.: 19/396,054

(22) Filed: Nov. 20, 2025

Related U.S. Application Data
(60) Provisional application No. 63/722,757, filed on Nov. 20, 2024.

(51) Int. Cl. H04R 3/12; G01B 21/16; H03G 3/20

(52) U.S. Cl. CPC H04R 3/12; G01B 21/16; H03G 3/20; H04R 2420/07; H04R 2430/01

(57) ABSTRACT

A method of automatically controlling speaker volume of a worksite audio device includes acquiring input from a sensor indicative of a distance between a power tool and the worksite audio device, wherein the power tool includes wireless communication capabilities. The method determines a first user distance from a speaker based on the sensor input and correlates a user-defined speaker volume with the first user distance. As the power tool moves to a different location, a second user distance is determined. A new speaker volume is set based on the first user distance, the user-defined speaker volume, and the second user distance, using the power tool's location to calculate the appropriate volume adjustment. The speaker is controlled to output audio at the new speaker volume based on the power tool's current position relative to the worksite audio device.

### CROSS-REFERENCE TO RELATED APPLICATIONS

This application claims the benefit of U.S. Provisional Application No. 63/722,757 filed on Nov. 20, 2024, the entire contents of which is incorporated herein by reference.

### BACKGROUND

Audio devices are frequently used in worksites to provide music or other entertainment to people in the surrounding area. Such devices may include jobsite radios or speakers, and these devices are generally durable for transport to and use in worksites. Furthermore, such devices can include a single speaker for directing sound in one general direction, or may include a plurality of speakers for directing sound in multiple directions around the device.

### SUMMARY

According to one aspect of the present disclosure, a method of automatically controlling speaker volume of a worksite audio device can be provided. The method can include acquiring input from a sensor indicative of a distance between a power tool and the worksite audio device, where the power tool includes wireless communication capabilities. The method can include determining a first user distance from a speaker of the worksite audio device based on the input from the sensor. The method can include correlating a user-defined speaker volume with the first user distance, wherein the user-defined speaker volume is a current volume at which the speaker outputs audio as set by a user. The method can include determining a second user distance from the speaker based on the input from the sensor as the power tool moves to a different location. The method can include setting a new speaker volume of the audio based on the first user distance, the user-defined speaker volume, and the second user distance, where the power tool's location is used to calculate the appropriate volume adjustment. The method can include controlling the speaker to output the audio at the new speaker volume based on the power tool's current position relative to the worksite audio device.

In some examples, the sensor may be a received signal strength indicator sensor that determines user distance by measuring wireless signal strength from the power tool.

In some examples, the worksite audio device may include multiple speakers, and the method may further include individually controlling different volume outputs for each of the multiple speakers based on respective distances to the power tool.

In some examples, the worksite audio device may be part of a daisy-chained network of multiple worksite audio devices, and the method may further include coordinating volume adjustments across the multiple worksite audio devices based on respective distances to the power tool.

In some examples, coordinating volume adjustments may include calculating differential volume levels for each worksite audio device in the daisy-chained network such that a right sound source increases its volume to a greater extent than a left sound source when the power tool is positioned farther from the right sound source than from the left sound source.

In some examples, the method may further include storing the user-defined volume level and the first user distance in memory after a waiting period allowing a user with the power tool to walk back to their working location.

In some examples, the method may further include detecting multiple power tools with wireless communication capabilities in range of the worksite audio device, where acquiring input from the sensor includes acquiring input indicative of the distance between a closest power tool of the multiple power tools and the worksite audio device.

According to another aspect of the present disclosure, a worksite audio device can be provided. The worksite audio device can include a housing with a front side and a rear side. The worksite audio device can include a speaker disposed on the front side of the housing. The worksite audio device can include an audio circuit coupled to the speaker to provide an audio signal to the speaker, where the speaker outputs audio corresponding to the provided audio signal. The worksite audio device can include a sensor positioned along the front side of the housing and configured to acquire input indicative of distance information from a power tool with wireless communication capabilities. The worksite audio device can include a controller in communication with the sensor, the speaker, and the audio circuit, the controller including a processor and a memory storing program instructions that, when executed by the processor, causes the controller to acquire input from the sensor indicative of a distance of the power tool from the speaker, determine a first user distance from the speaker based on the input from the sensor, correlate a user-defined speaker volume with the first user distance, where the user-defined speaker volume is a current volume at which the speaker outputs audio as set by a user, determine a second user distance from the speaker based on the input from the sensor as the power tool moves to a different location, set a new speaker volume of the audio based on the first user distance, the user-defined speaker volume, and the second user distance, where the power tool's location is used to calculate the appropriate volume adjustment, and control the speaker to output the audio at the new speaker volume based on the power tool's current position relative to the worksite audio device.

In some examples, the sensor may be a received signal strength indicator sensor configured to determine user distance by measuring wireless signal strength from the power tool.

In some examples, the power tool may include a battery pack with integrated wireless communication capabilities for transmitting the distance information to the sensor.

In some examples, the worksite audio device may further include multiple speakers disposed on the housing, wherein the controller is configured to individually control different volume outputs for each of the multiple speakers based on respective distances to the power tool.

In some examples, the sensor may be configured to acquire a unique identification code from the power tool.

In some examples, the controller may acquire the input from the sensor indicative of the distance of the power tool from the speaker via communication with a mobile device wirelessly connected to the power tool.

In some examples, the sensor may acquire distance information for multiple power tools, and the controller may be configured to process the distance information from the closest power tool to the speaker.

According to yet another aspect of the present disclosure, a daisy-chained worksite audio system can be provided. The daisy-chained worksite audio system can include multiple worksite audio devices, each worksite audio device including a housing, a speaker disposed on the housing, a sensor configured to acquire input indicative of distance information from a user, and a controller configured to process the distance information to determine a distance between the user and the speaker. The daisy-chained worksite audio system can include a bidirectional communication link connecting the multiple worksite audio devices. The controllers of the multiple worksite audio devices can be configured to collectively coordinate volume adjustments of the speakers across the multiple worksite audio devices based on the respective distances to the user.

In some examples, each sensor may be a received signal strength indicator sensor configured to measure wireless signal strength from one of a user's mobile device, a tag having a Bluetooth beacon, a power tool, or a power tool battery.

In some examples, the multiple worksite audio devices may be wirelessly connected to a single auxiliary device, allowing the multiple worksite audio devices to be synced to emit the same audio output as controlled by the auxiliary device.

In some examples, the controllers may communicate with one another through the bidirectional communication link to coordinate the volume adjustments in real-time.

In some examples, the sensor may be configured to acquire input indicative of distance information from the user by detecting distance information to a power tool, and the power tool may include integrated wireless communication capabilities for communicating with the sensor.

In some examples, the power tool may be configured to transmit a unique identification code that allows the controllers to distinguish between multiple power tools.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is an isometric view of one example of a worksite audio device.

FIG. 2 is an isometric view of another example of a worksite audio device.

FIG. 3 is an isometric view of yet another example of a worksite audio device.

FIGS. 4A and 4B are isometric views of another example of a worksite audio device.

FIGS. 5A and 5B are isometric views of another example of a worksite audio device.

FIG. 6 is an example block diagram of components of a control system of a worksite audio device.

FIG. 7 is a diagram of user locations relative to a sound source.

FIG. 8 is a diagram of an example audio system.

FIG. 9 is a flowchart of an example method for automatically controlling speaker volume of a worksite audio device based on a user distance relative to the worksite audio device.

FIGS. 10A and 10B are diagrams illustrating network configurations for multiple sound sources in communication with an auxiliary device.

### DETAILED DESCRIPTION

The following discussion is presented to enable a person skilled in the art to make and use embodiments of the invention. Given the benefit of this disclosure, various modifications to the illustrated embodiments will be readily apparent to those skilled in the art, and the principles herein can be applied to other embodiments and applications without departing from embodiments of the invention. Thus, embodiments of the invention are not intended to be limited to embodiments shown, but are to be accorded the widest scope consistent with the principles and features disclosed herein.

The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Generally, in some examples, a worksite audio device can detect a distance of a user from the audio device and adjust its volume based on the detected distance. Because volume diminishes with distance, the ability to adjust volume automatically prevents the audio device from being too quiet in larger distances or too loud in smaller distances as the user moves.

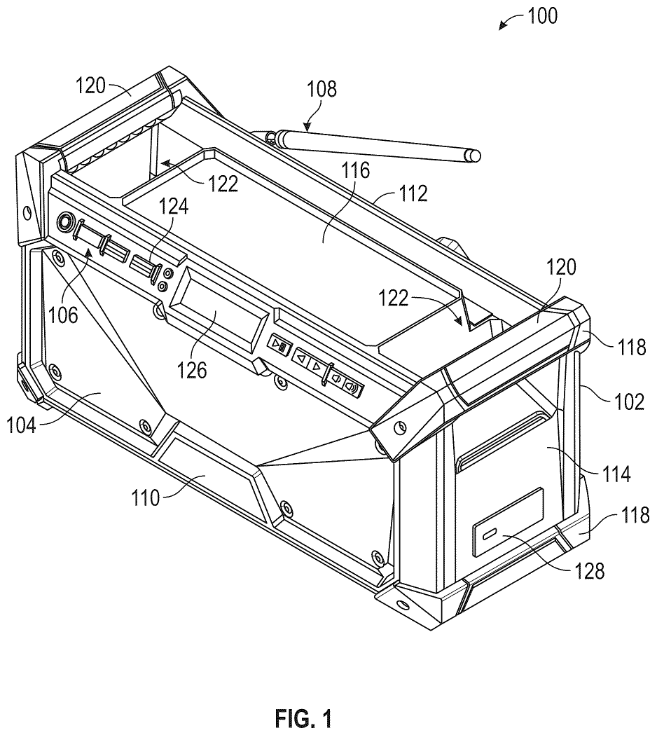

With reference to FIG. 1, an audio device 100 according to an example of the present disclosure is shown. Audio devices like the audio device 100 are often found on construction sites in order to provide music or other audio to the people in the surrounding area. As such, the audio device 100 may be referred to as a worksite audio device 100 (for example, a jobsite radio). Furthermore, the audio device 100 can be portable and battery powered, although other configurations are possible. For example, the audio device 100 can be powered by alternative power sources, such as AC power through a wall outlet or DC power. The audio device 100 can generally be durable for transport to or use in construction areas or other job sites. In one example, the audio device 100 includes a housing 102, a speaker 104, a user interface 106, and an antenna assembly 108.

More specifically, as shown in FIG. 1, the housing 102 may contain the speaker 104. The housing 102 may be generally rectangular cuboid and includes a front side 110, a rear side 112, a pair of sidewalls including a first sidewall 114 and an opposing second sidewall (not shown in FIG. 1), a top surface 116, and an opposite bottom surface (not shown in FIG. 1). As shown in FIG. 1, the speaker 104 can be positioned along, or coupled to the front side 110 of the housing 102. For example, the speaker 104 can span across the front side 110 of the housing 102. In some embodiments, the speaker 104 can include multiple speakers (e.g., a right-side speaker adjacent the first sidewall 114 and a left-side speaker adjacent the second sidewall) and/or multiple speaker elements (e.g., one or more woofers and one or more tweeters) to emit balanced and/or directional sound from the audio device 100.

The audio device 100 may also include a roll cage or frame 118 mounted on the housing 102. The roll cage 118 may define one or more handles 120. The roll cage 118 may protect the housing 102 from damage in the event of a drop or other shock to the audio device 100. The handles 120 may be provided along or adjacent the top surface 116 of the housing 102. The handles 120 may be gripped by a user to transport the portable audio device 100. For example, in the illustrated embodiment, a hand-receiving space 122 is defined between the housing 102 and each of the handles 120. The hand-receiving space 122 is dimensioned to accommodate a user's hand and fingers, providing sufficient clearance for comfortable gripping and manipulation of the handles 120. In this way, the hand-receiving space 122 allows users to lift, carry, and position the audio device 100 with ease. In some embodiments, the hand-receiving space 122 may be sized to accommodate users wearing work gloves, ensuring that the audio device 100 remains easily transportable even when users are wearing protective equipment commonly used in construction and industrial settings.

The audio device 100 also includes the user interface 106. In some embodiments, the user interface 106 may include a plurality of buttons 124 which allow a user to provide input to control the audio output by the speaker 104. These buttons 124 may control various device parameters including volume adjustment, power on/off functionality, Bluetooth connectivity, daisy-chaining capabilities with other audio devices, and media control functions such as skip or replay, although other button configurations and control options are possible.

The user interface 106 may also include a display 126 to communicate information to the user about the audio output, the audio device, or another connected device. Additionally or alternatively, the display 126 may include a touch interface that allows a user to provide input to control the audio output by the speaker 104. The user interface 106 may be positioned on the front side 110 of the housing 102 adjacent the speaker 104. For example, the user interface 106 may be positioned above the speaker 104, although other configurations are possible. In some embodiments, the audio device 100 is capable of establishing a Bluetooth connection to a user's mobile device, allowing the mobile device to serve as an extended or alternative display interface. This wireless connectivity allows users to control audio functions, view device status, and access additional features through their mobile device's screen, providing enhanced functionality and convenience, particularly when the audio device 100 is positioned at a distance from the user's working location.

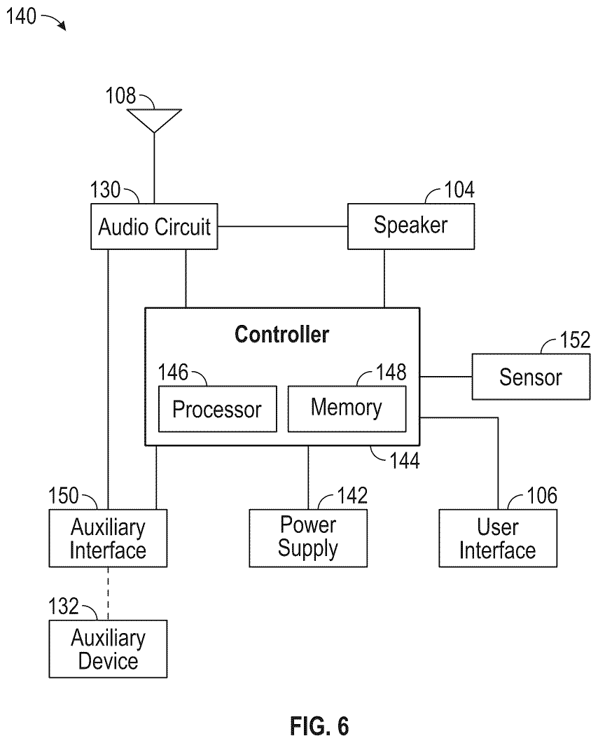

Additionally, in some embodiments, the audio device 100 may include a radio system including the antenna assembly 108 mounted on and/or extending from the housing 102. As further described below, the audio device 100 may receive radio signals via the antenna assembly 108. An audio circuit 130 (shown in FIG. 6) may then issue a corresponding audio signal to the speaker 104, which outputs audio in response. Furthermore, as shown in FIG. 1, the housing 102 may include a panel 128 on the first sidewall 114 that is movable to an open position to expose one or more ports (not shown) that allows an auxiliary device 132 (shown in FIG. 6) to be connected to the audio device 100 via a wired connection. The audio circuit 130 may then issue a corresponding audio signal from the auxiliary device 132 to the speaker 104, which outputs audio in response. For example, the ports may include a power connection port, e.g., a DC power connection, such as a USB type port. The USB type port can be used to connect the auxiliary device 132 to the audio circuit 130, or can be used to provide power from an attached battery pack (not shown) to the audio device 100. As another example, the ports can also include an AUX type port, which can be used to connect the auxiliary device 132 to the audio circuit 130.

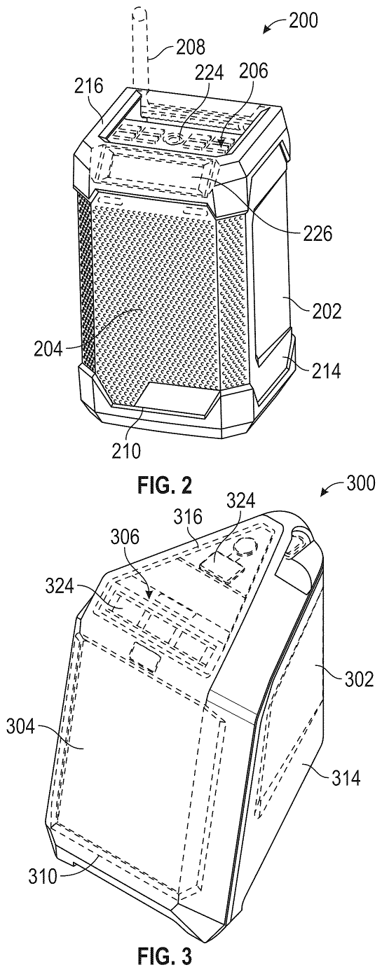

FIG. 2 illustrates another audio device 200 according to another example of the present disclosure. The audio device 200 may also be considered a worksite audio device, such as a jobsite radio. In this embodiment, the audio device 200 may include the same or similar structural features as the audio device 100 of FIG. 1 and will be referenced with reference numerals increased by 100 as were similarly described above in connection with the audio device 100 of FIG. 1, unless otherwise stated. For example, as shown in FIG. 2, the audio device 200 can include a housing 202, a speaker 204, a user interface 206, an antenna assembly 208, a front side 210, a first sidewall 214, a top surface 216, buttons 224, and a display 226.

FIG. 3 illustrates yet another audio device 300 according to another example of the present disclosure. The audio device 300 may also be considered a worksite audio device, such as a jobsite speaker. In this embodiment, the audio device 300 may include the same or similar structural features as the audio device 100 and will be referenced with reference numerals increased by 200 as were similarly described above in connection with the audio device 100 of FIG. 1, unless otherwise stated. For example, as shown in FIG. 3, the audio device 300 can include a housing 302, a speaker 304, a user interface 306, a front side 310, a first sidewall 314, a top surface 316, and buttons 324 (e.g., without a display). In some embodiments, the audio device 300 may be considered a speaker only, rather than a radio and, thus, may not include an antenna assembly 308. However, in other embodiments, the audio device 300 may include an antenna assembly.

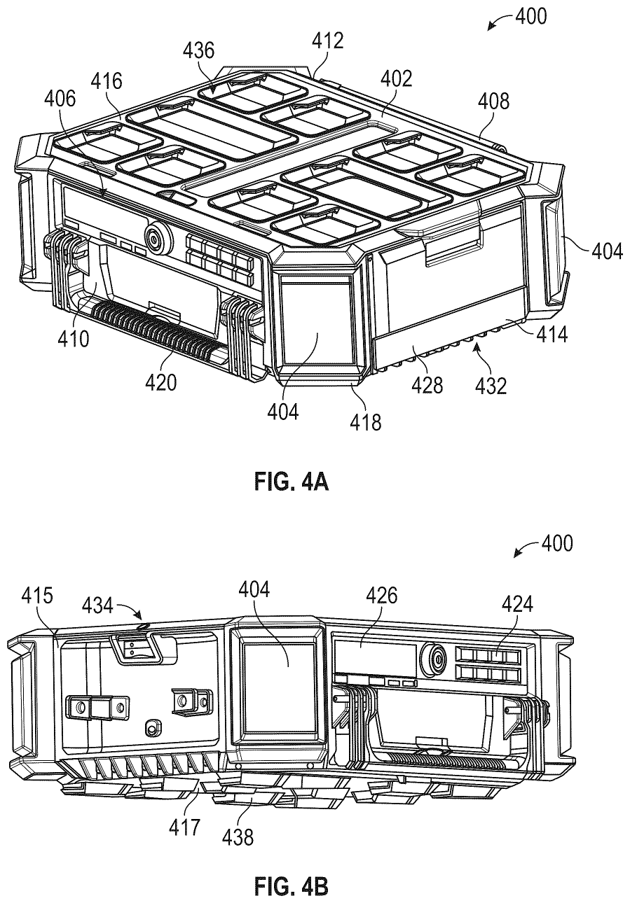

FIGS. 4A and 4B illustrate another audio device 400 according to another embodiment of the present disclosure. The audio device 400 may also be considered a worksite audio device, such as a jobsite speaker. In this embodiment, the audio device 400 may include the same structural features as the audio device 100 of FIG. 1 and will be referenced with reference numerals increased by 300 as were similarly described above in connection with the audio device 100 of FIG. 1, unless otherwise stated. In particular, as shown in FIGS. 4A and 4B, the audio device 400 can include a housing 402, a speaker 404, a user interface 406, an antenna assembly 408, a front side 410, a rear side 412, a first sidewall 414 (and an opposite second sidewall 415, shown in FIG. 4B), a top surface 416 (and an opposite bottom surface 417, shown in FIG. 4B), and a frame 418.

In this embodiment, the audio device 400 includes four speakers 404 that are positioned at each corner of the housing 402, which allows the audio device 400 to provide 360-degree sound distribution, where audio is projected in multiple directions simultaneously and across a wider area around the worksite audio device 400. Furthermore, a handle 420 extends from the front side 410 below the user interface 406. The user interface 406 also includes buttons 424 and a display 426. A panel 428 on the first sidewall 414 covers a charging compartment 432 that can receive and charge a battery or a mobile device. On the second side wall 415, as shown in FIG. 4B, a storage compartment 434 is disposed and can store an electrical cable that in some cases may power the audio device 400 (e.g., by being plugged into an external power outlet), although other configurations are possible.

Referring still to FIGS. 4A and 4B, the audio device 400 can be configured to be stackable within modular tool storage systems used in worksite environments. For example, the audio device 400 includes complementary engagement components that allow secure vertical stacking and coupling with compatible storage containers. In particular, female engagement pieces 436 are positioned on the top surface 416 and are configured to receive and securely engage corresponding male engagement pieces of a storage container positioned above the audio device 400. These female engagement pieces 436 may include recessed channels, grooves, or receptacles that provide alignment and mechanical retention, although other configurations are possible. Correspondingly, male engagement pieces 438 extend from the bottom surface 417 of the housing 402 and are configured to be received within and secured by corresponding female engagement pieces of a storage container positioned below the audio device 400. Alternatively, the male engagement pieces 438 may act as a ground-engaging interface for the audio device 400, although other configurations are possible. The male engagement pieces 438 may include protruding tabs or connectors that mate with the female components to create a stable, interlocked connection.

This dual engagement system allows the audio device 400 to function as an intermediate component in a vertical stack, simultaneously connecting to containers both above and below. The stackable design allows users to create customized storage towers that incorporate the audio device 400 alongside their tool storage containers, maximizing workspace organization while maintaining easy access to both audio functionality and stored equipment. Alternative configurations are possible in some embodiments, such as positioning female engagement pieces 436 on the bottom surface 417 and male engagement pieces 438 on the top surface 416, or providing both male and female engagement pieces 436, 438 on either the top surface 416 or bottom surface 417, or limiting engagement pieces to only one surface while leaving the other surface without engagement components.

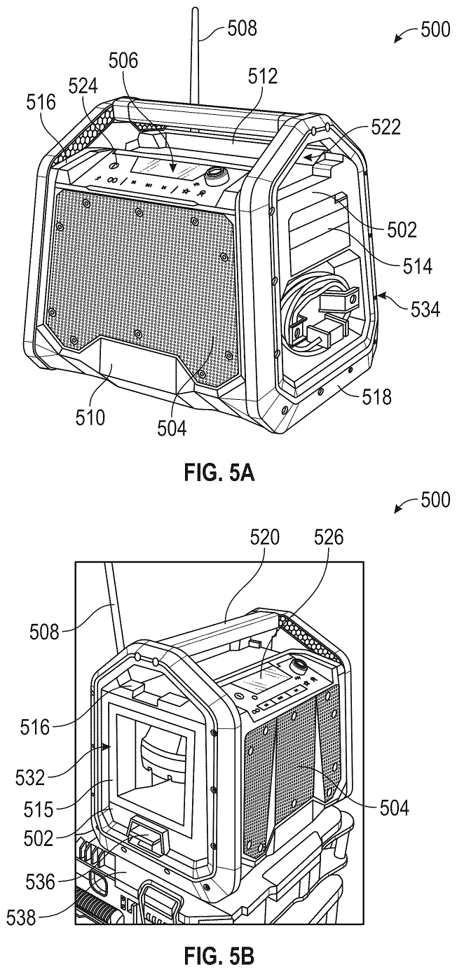

FIGS. 5A and 5B illustrate another audio device 500 according to another embodiment of the present disclosure. The audio device 500 may also be considered a worksite audio device, such as a jobsite speaker. In this embodiment, the audio device 500 may include the same or similar structural features as the audio device 100 of FIG. 1 and will be referenced with reference numerals increased by 400 as were similarly discussed above in connection with the audio device 100 of FIG. 1, unless otherwise stated. In particular, as shown in FIGS. 5A and 5B, the audio device 500 can include a housing 502, a speaker 504, a user interface 506, an antenna assembly 508, a front side 510, a rear side 512, a first sidewall 514 (and an opposite second side wall 515, shown in FIG. 5B), a top surface 516, a bottom surface (not shown in FIGS. 5A and 5B) and a frame 518.

In this embodiment, the audio device 500 includes a handle 520 that extends from the frame 518 adjacent the top surface 516 so that a hand receiving space 522 is defined between the handle 520 and the top surface 516. The hand receiving space 522 is dimensioned to accommodate a user's hand and fingers, providing sufficient clearance for comfortable gripping and manipulation of the handle 520. This configuration allows users to lift, carry, and position the audio device 500 with ease, while the handle 520 provides a secure grip point that distributes the weight of the device across the user's hand for improved ergonomics during transport.

Referring still to FIGS. 5A and 5B, the user interface 506 also includes buttons 524 and a display 526. The second sidewall 515 can include a charging compartment 532 that can receive and charge a battery or a mobile device. On the first side wall 514, a storage compartment 534 is positioned and can store an electrical cable that in some cases may power the audio device 500 (e.g., by being plugged into an external power outlet). To facilitate manipulation and movement of the audio device 500, a grip 536 is disposed below the charging compartment 532 on the second sidewall 515. The grip 536 provides an additional gripping location that allows users to securely hold and maneuver the audio device 500 during transport or repositioning. This complements the primary handle 520 and allows for improved control when lifting, carrying, or adjusting the position of the audio device 500.

The audio device 500 incorporates a stackable architecture that allows seamless integration within modular storage systems, for example, as shown in FIG. 5B where the audio device 500 secured to a storage container 538. In this embodiment, the stackable coupling system of the audio device 500 utilizes only male engagement pieces (not visible in FIGS. 5A and 5B, though similar to male engagement pieces 438 shown in FIG. 4B) that extend from the bottom surface of the housing 502. These male engagement pieces can be designed to interface with corresponding female engagement pieces integrated into the upper surface of the storage container 538 (not visible in FIG. 5B, though similar to female engagement pieces 436 shown in FIG. 4A), creating a secure mechanical connection that prevents lateral movement and vertical separation during transport or use. This coupling mechanism allows the audio device 500 to maintain stable positioning when positioned on top of the storage container 538, while still allowing for controlled engagement and disengagement when reconfiguration of the storage system is required. This stackable design allows users to build comprehensive worksite organization systems where the audio device 500 can be positioned on top of storage containers, providing convenient access to audio functionality while maintaining the structural integrity of the assembly.

Turning now to FIG. 6, an example schematic view of a control system 140 that may be incorporated into any of the above-described audio devices 100, 200, 300, 400, 500 is illustrated. It should be noted that while the following discussion describes audio device 100 in particular, the same or similar principles, features, and functionality can apply equally to audio devices 200, 300 400, and 500 unless otherwise specified. For example, the control system 140 can include a power supply 142, a controller 144 comprising a processor 146 and memory 148, the user interface 106, the audio circuit 130, the speaker 104, the antenna assembly 108, an auxiliary interface 150, and a sensor 152. The components of the control system 140 are illustrated as separate blocks in FIG. 6, although one or more components may be combined together in some embodiments. For example, in some instances, the auxiliary interface 150 and/or the audio circuit 130, or portions thereof, may be part of the controller 144.

Generally, the power supply 142 can provide operational power to components of the audio device 100, such as the controller 144. For example, the power supply 142 can receive power from a DC source plugged into the audio device 100 and/or from a removable battery connected to the audio device 100 (e.g., through a port at the panel 128 of the housing 102 or via a charging compartment 532 of the audio device 100).

In some embodiments, the controller 144 may be operable to receive input from various components of the audio device 100 and to control various components of the audio device 100 based on this input. For example, the controller 144 can be coupled to the user interface 106, the audio circuit 130, the speaker 104, the auxiliary interface 150, the sensor 152, and the power supply 142. As shown in FIG. 6, the controller 144 can include the processor 146 connected to the memory 148. The memory 148 can be a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The program storage area include instructions that, when executed by the processor 146, cause the controller 144 to operate the audio device 100. In some instances, the data storge area can include a plurality of look up table of values. For example, at least one stored look up table may comprise volume level data, as further described below.

In some embodiments, the controller 144 controls operation of the audio circuit 130. For example, the audio circuit 130 can provide audio signals to the speaker 104. In some instances, the audio circuit 130 includes filters, equalizers, etc. to modify the audio signal before sending to the speaker 104. As shown in FIG. 6, the audio circuit 130 may be selectively connected to the antenna assembly 108 and/or to one or more auxiliary devices 132 (e.g., phone, tablet, smartwatch, computer, MP3 player, or any other portable device with access to audio information) via the auxiliary interface 150. For example, in some instances, the auxiliary interface 150 can include a wireless unit to enable wireless connection (e.g., Bluetooth®) between the auxiliary device 132 and the audio device 100. Additionally, in some instances, the auxiliary interface 150 can include one or more communication ports (such as a data port and/or an auxiliary input port, as described above with respect to the housing panel 128) to enable wired connections between the auxiliary device 132 and the audio device 100.

Accordingly, the audio circuit 130 can receive radio signals from the antenna assembly 108 or audio signals from one or more auxiliary devices 132 and provides corresponding audio signals to the speaker 104, which outputs audio in response. The audio circuit 130 can determine which audio signal to output based on an audio select signal from the controller 144. That is, the controller 144 can generate an audio select signal based on inputs from the user interface 106 and/or the auxiliary device 132.

Furthermore, in some embodiments, the controller 144 controls operation of the speaker 104. For example, the controller 144 can control the speaker 104 by controlling a volume of the audio output from the speaker 104 and/or a directionality of the audio output.

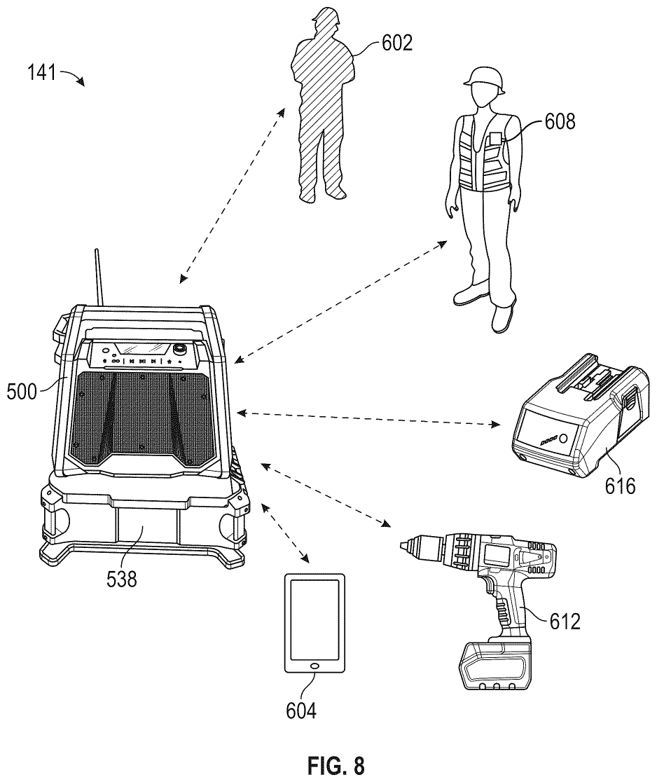

In some embodiments, the controller 144 can control operation of the speaker 104 based on input from the sensor 152. More specifically, in some embodiments, the sensor 152 can be configured to provide information to the controller 144 corresponding to a distance of a user or object from the audio device 100. In this manner, the audio device 100 can form an audio system 141 with one or more connected devices, as shown in FIG. 8, where the audio device 100 is configured, via the sensor 152, to detect or communicate with the connected device(s) and, in response, adequately adjust audio output, as will be further described below. In some embodiments, however, the audio system 141 may solely include the audio device 100 (i.e., without additional connected devices) that is configured, via the sensor 152, to detect a user and, in response, adequately adjust audio output.

Accordingly, for example, the sensor 152 can be a distance sensor such as a time of flight (TOF) sensor, a light detection and ranging (LIDAR) sensor, a received signal strength indicator (RSSI)-type sensor, a radar sensor (e.g., a millimeter wave (mmWave) radar sensor), a thermal imaging sensor, an ultrasonic sensor, a passive infrared (PIR) sensor, a camera-based sensor with computer vision capabilities, or another type of sensor capable of detecting user or object presence and distance. In particular, the TOF sensor operates by emitting light pulses and measuring the time required for the light to return after reflecting off a user (e.g., user 602, shown in FIG. 8) or object, providing accurate distance measurements of a user relative to the audio device 100. The LIDAR sensor uses laser light to create detailed distance maps of the surrounding environment, allowing for user location tracking. The RSSI-type sensor determines distance by measuring the strength of wireless signals from a user's mobile device (e.g., an auxiliary device 132 such as mobile device 604, shown in FIG. 8) or wearable technology (e.g., tag 608, shown in FIG. 8). The mmWave radar sensor can detect movement and distance through radio frequency signals. The thermal imaging sensor detects heat signatures from users, allowing for distance calculation based on the size and intensity of the thermal signature. The ultrasonic sensor emits high-frequency sound waves and measures the time for echo return to determine distance. The PIR sensor detects infrared radiation emitted by human bodies and can be configured to estimate distance based on signal strength and detection patterns. Camera-based sensors with computer vision can analyze visual data to identify users and calculate their distance from the audio device 100 through image processing algorithms.

The sensor 152 can be located along the front side 110 of the housing 102 to optimize detection of users positioned in front of the speaker 104. However, in other embodiments, the sensor 152 can be located along other sides of the housing 102, such as the rear side 112, the first sidewall 114, the second sidewall 115, and/or the top surface 116, to provide broader coverage areas and accommodate different worksite layouts where users may approach the audio device 100 from various directions.

To further enhance detection capabilities, multiple sensors 152 of the same or different types can be incorporated around the housing 102 to create a comprehensive detection system. Sensors 152 may be distributed across the front side 110, rear side 112, sidewalls 114, 115 and top surface 116 of the housing 102 to create 360-degree detection capabilities that can simultaneously track multiple users positioned around the audio device 100. In some embodiments, the worksite audio device 100 may incorporate sensor arrays that include combinations of various sensor types (e.g., time-of-flight sensors, LIDAR sensors, ultrasonic sensors, thermal imaging sensors, and camera-based computer vision systems) operating simultaneously to provide redundant distance measurements and improved accuracy through sensor fusion techniques, with directional sensor arrays and/or sensor clusters providing localized multi-sensor fusion at multiple points around the device 100.

Building upon this multi-sensor foundation, the controller 144 can leverage this multi-sensor architecture by implementing sophisticated data processing algorithms. In some examples, the controller 144 can compare distance calculations from different sensors 152 and use sensor fusion algorithms that process data from multiple sensors 152 in real-time to generate composite distance measurements with enhanced precision. In some cases, the controller 144 can use weighted averaging algorithms that assign different confidence levels to each sensor type based on environmental conditions, where optical sensors 152 may receive higher weighting in well-lit conditions while ultrasonic sensors 152 may be prioritized in dusty or visually obscured environments. The controller 144 may also include cross-validation protocols that compare distance measurements from different sensor types to identify and compensate for sensor-specific errors or malfunctions.

The controller 144 may also incorporate advanced signal processing algorithms that filter and condition raw sensor data before fusion processing. In some embodiments, the system 141 may use digital filtering techniques to remove noise, outliers, and measurement artifacts from individual sensor streams, improving the quality of input data for fusion algorithms. The multi-sensor system 141 may implement statistical analysis algorithms that evaluate the consistency and reliability of sensor measurements over time, identifying sensors that may require recalibration or replacement. In some cases, the controller 144 may use trend analysis to detect gradual sensor degradation and proactively adjust fusion algorithms to maintain measurement accuracy.

To ensure reliable operation, the multi-sensor architecture may provide fault tolerance capabilities that maintain distance detection functionality even when individual sensors 152 fail or become obstructed. In some embodiments, the controller 144 may include sensor health monitoring algorithms that continuously evaluate the performance of each sensor 152 and detect degraded operation or complete failures. The controller 144 may implement graceful degradation protocols that automatically reconfigure sensor fusion algorithms when sensors 152 become unavailable, redistributing weighting factors among remaining functional sensors 152 to maintain distance measurement accuracy. In some cases, the controller 144 may include sensor cleaning detection that can identify when sensors 152 become obstructed by dust, debris, or other environmental contaminants and alert users (e.g., on the display 126) to maintenance requirements.

Beyond basic processing and fault tolerance, the controller 144 may also incorporate machine learning algorithms that continuously optimize sensor fusion parameters based on historical performance data and environmental conditions. In some embodiments, the controller 144 may use neural network algorithms (e.g., stored in memory 148) that learn to correlate sensor readings with actual user distances, improving accuracy over time as the system 141 gains experience in specific worksite environments. The controller 144 may implement Kalman filtering techniques to process sensor data streams to predict user movement patterns and provide smoother distance tracking with reduced noise and measurement fluctuations. In some cases, the controller 144 may use particle filtering algorithms that maintain multiple hypotheses about user positions and continuously update probability distributions based on incoming sensor data.

In some embodiments, the control system 140 may also include automated sensor calibration systems that periodically verify and adjust sensor accuracy using known reference distances or calibration targets. In some embodiments, the controller 144 may perform cross-sensor calibration where sensors 152 with different measurement principles are used to validate and correct each other's readings. The controller 144 may implement timing synchronization to ensure that distance measurements from different sensors correspond to the same temporal instant, preventing errors that could occur due to user movement during the measurement process. In some cases, the controller 144 may include sensor data timestamping and interpolation algorithms that can correlate measurements taken at slightly different times.

In some embodiments, the control system 140 may also include environmental sensing capabilities with additional sensors 152 that monitor ambient conditions and automatically adjust sensor operation parameters. For example, in such embodiments, the control system 140 may incorporate ambient light sensors 152 that detect lighting conditions and optimize the operation of optical sensors such as cameras and LIDAR systems accordingly. The control system 140 may include temperature and humidity sensors 152 that provide environmental data for compensating ultrasonic sensor measurements, which can be affected by air density variations. The controller 144 may implement adaptive sensor selection algorithms that automatically prioritize different sensor types based on detected environmental conditions, switching between sensor combinations dynamically using thermal imaging sensors in low-light conditions, optical sensors in well-lit environments, and ultrasonic sensors in dusty or visually obscured conditions.

In some embodiments, the audio device 100 may support simultaneous tracking of multiple users through unique identifier systems, where each user carries a distinct removable tag 608 (shown in FIG. 8) or uses a registered mobile device 604. In some examples, the audio device 100 may calculate volume levels based on the closest user, the average distance of all detected users, or weighted algorithms that prioritize certain users based on predetermined preferences. The controller 144 may include user priority settings that allow supervisors or lead workers to have their distance measurements weighted more heavily in volume calculations. In some cases, the controller 144 may support zone-based volume control where different areas around the audio device 100 maintain different volume levels based on typical user activities in those zones.

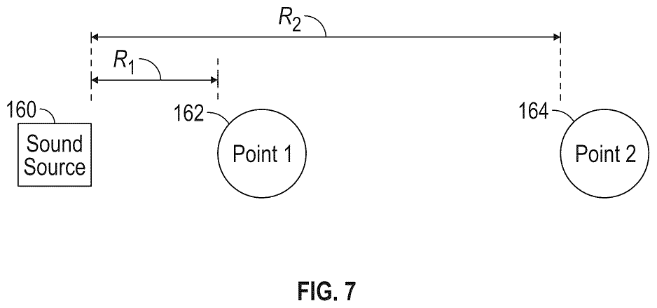

In view of the above, FIG. 7 illustrates a sound source 160 (e.g., audio device 100), a first user location 162 (“Point 1”) at a first distance, R1, from the sound source 160, and a second user location 164 (“Point 2”) at a second distance, R2, from the sound source 160. Because the volume of audio output from the sound source 160 diminishes with distance, the audio output may be at a sufficient volume level for a user at the first user location 162, but too quiet if the user is at the second user location 164. This creates a practical problem in worksite environments where users frequently move between different locations while performing various tasks, requiring them to manually adjust the volume each time they change position relative to the audio device 100. Conversely, the audio output may be at a sufficient volume level for a user at the second user location 164, but too loud if the user is at the first user location 162, potentially causing discomfort or even hearing damage if the user approaches the audio device 100 while it is set to a high volume for distant listening. In traditional audio systems, this distance-related volume variation requires constant manual intervention, interrupting workflow and reducing productivity in worksite environments.

According to some embodiments, the controller 144, using the sensor(s) 152, can track a user's location with respect to the audio device 100 and adjust a volume level of the audio output of the speaker 104 automatically in real-time, thus preventing the audio device 100 from being too quiet in larger distances or too loud in smaller distances as a user moves. This automatic volume adjustment system 141 eliminates the need for users to manually control volume settings as they move throughout the worksite, allowing them to maintain focus on their primary tasks while ensuring consistent audio quality at their current location. The system 141 can continuously monitor user position and make gradual volume adjustments to prevent abrupt changes that might be jarring or distracting, while also accounting for ambient noise levels and environmental factors that may affect optimal listening volume.

As briefly discussed above, and turning now to FIG. 8, the sensor 152 may include an RSSI-type sensor that determines a distance by measuring the strength of wireless signals from a user's mobile device or a wearable technology. In particular, a user's mobile device 604 may range from a user's mobile phone, a tablet, a remote that can be paired with the audio device 100, or other portable electronic devices capable of wireless communication (e.g., through Bluetooth pairing). The RSSI sensor 152 operates by analyzing the received signal strength indicator values from these devices 604, where stronger signals typically indicate closer proximity and weaker signals indicate greater distance. The controller 144 can execute algorithms that correlate specific RSSI values to distance measurements, accounting for environmental factors such as obstacles, interference, and signal propagation characteristics in worksite environments.

In other examples, a user's smart watch or smart glasses may be connected to and indicate the distance of a user relative to the audio device 100. These smart devices can utilize their built-in wireless communication capabilities, such as Bluetooth, Wi-Fi, or cellular connectivity, to establish communication with the audio device 100. The mobile device 604 or other smart devices may also incorporate additional sensors, such as accelerometers or GPS modules, to provide enhanced location tracking and movement detection capabilities that can supplement the distance measurements obtained through wireless signal strength analysis. In such examples, the auxiliary interface 150, receiving location data from the mobile device 604, may be considered a sensor of the audio device 100.

Alternatively or additionally, this wireless signal may be measured from a wearable technology of a user such as a removable tag 608 wirelessly connected to the audio device 100. In some examples, the removable tag 608 may be attached and compatible with conventional objects worn by a user on a worksite, such as a vest, a hard hat, safety glasses, or a tool belt. The removable tag 608 can include a low-power wireless transmitter, such as a Bluetooth Low Energy (BLE) beacon, that periodically broadcasts identification signals at predetermined intervals, such as about every 250 milliseconds, or about every 500 milliseconds, or about every 750 milliseconds, or about every 1 second, although other intervals are possible. The tag 608 may be designed to withstand harsh worksite conditions, including exposure to dust, moisture, vibration, and impact, while maintaining reliable wireless connectivity. The tag 608 can be powered by a replaceable battery with extended life, or may include energy harvesting capabilities such as solar cells or kinetic energy converters to extend operational duration.

The removable tag 608 may include multiple attachment mechanisms to accommodate various worksite clothing and equipment. In some embodiments, the tag 608 may feature magnetic attachment systems for metal hard hats, clip-on mechanisms for safety vests, adhesive backing for temporary attachment to clothing, or integrated mounting systems compatible with existing safety equipment such as tool belts or harnesses. The removable tag 608 may incorporate environmental protection features, including IP65 or higher ingress protection ratings to withstand dust, moisture, and chemical exposure common in worksite environments. The tag 608 may include shock-resistant housing materials and vibration dampening systems to maintain functionality despite impacts and mechanical stress. In some cases, the removable tag 608 may include multi-modal communication capabilities, supporting multiple wireless protocols simultaneously such as Bluetooth, Zigbee, and proprietary mesh networking protocols.

In other embodiments, a user's tool 612 or a tool battery 616 is able to wirelessly connect to a user's mobile device (e.g., mobile device 604) through a program application. For example, in some embodiments, a tool battery 616 can include wireless communication modules, such as Bluetooth or Wi-Fi transceivers, along with processing capabilities to manage communication protocols and data transmission. The battery 616 may also incorporate unique identification codes that allow the audio device 100 to distinguish between multiple users and their respective tools in multi-user worksite environments.

In some example, the program application for the user's mobile device 604 can be a dedicated mobile application designed specifically for worksite audio device management, or it can be integrated into existing tool management or worksite productivity applications. The application may provide a user interface that displays real-time distance information, volume settings, and audio device status, allowing users to monitor and control the automatic volume adjustment system 141. When the audio device 100 is also connected to the program application, the audio device 100 may be able to determine a user's distance relative to the audio device 100 regardless of the user's mobile phone location. More specifically, this configuration creates a triangulated positioning system where the tool 612 or tool battery 616 can serve as another accurate representation of the user's working location, since users typically keep their tools 612 in close proximity while working, whereas mobile phones 604 may be set aside or stored in pockets or bags. Accordingly, in some examples, the audio device 100 can use information from the mobile device 604, along with its location, to determine a location of the tool 612 or tool battery 616. In other examples, the mobile device 604 may directly provide the tool 612 or tool battery 616 location to the audio device 100, allowing the audio device 100 to determine the distance to the tool 612 or tool battery 616.

In some embodiments, the audio device 100 is able to directly wirelessly connect to the user's tool 612 or tool battery 616 so as to determine a user's distance from the audio device 100. This direct connection eliminates the need for intermediate devices or applications (e.g., a user's mobile device 604, as described above), providing a streamlined communication path between the audio device 100 and the user's tool 612 or tool battery 616. The tool 612 or tool battery 616 can include embedded wireless communication hardware, such as radio frequency transceivers, antennas, and signal processing circuits, that allow direct communication with the audio device 100. The wireless connection can utilize various communication protocols, including proprietary protocols optimized for worksite environments, standard protocols such as Bluetooth or Zigbee, or industrial communication standards designed for tool-to-tool connectivity. The tool 612 may also include onboard sensors, such as accelerometers or gyroscopes, that can detect tool usage patterns and movement, providing additional context information to the audio device 100 for more intelligent volume adjustment decisions based on whether the user is actively working or taking a break. In some embodiments, the battery 616 may incorporate unique device identifiers and authentication protocols to ensure secure communication with authorized audio devices 100.

In some cases, the power tool 612 or tool battery 616 may include GPS modules or indoor positioning system capabilities that can provide absolute location coordinates to the audio device 100, rather than the controller 144 determining relative distance measurements. The controller 144 may include its own GPS module to determine its own absolute location, allowing for the controller 144 to detect the distance between the audio device 100 and the power tool 612 or tool battery 616.

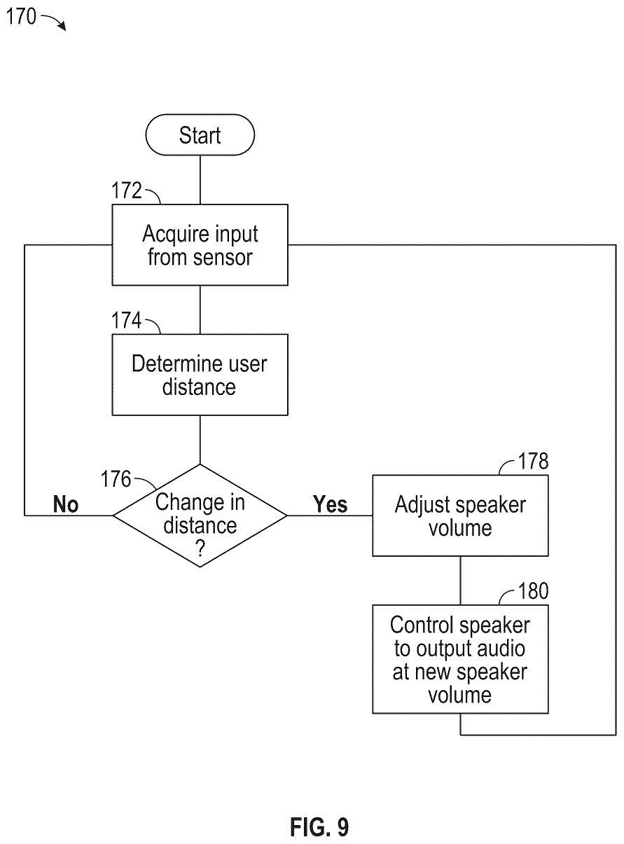

Turning now to FIG. 9, an example method 170 for automatically controlling volume output of an audio device 100, such as a jobsite radio or speaker is shown. Generally, one or more steps of this method 170 may be incorporated into software or firmware algorithms embedded within the controller 144. That is, the method steps may be stored in the form of instructions in a program storage area of the memory 148 of the controller 144, to be executed by the processor 146, causing the controller 144 to operate components of the audio device 100. Generally, the method 170 can include acquiring input from the sensor 152 (step 172); determining a user distance from the audio device 100 (step 174), and determining whether the user distance has changed (step 176). If not, the method 170 returns back to step 172. If user distance has changed, the method 170 further includes adjusting speaker volume (step 178), and controlling the speaker 104 to output audio at the new speaker volume (step 180).

In some embodiments, before the method 170 begins, the control system 140 may perform initial setup of the audio system 141 and configuration procedures to establish tracking parameters and network connections. For example, in some embodiments, the controller 144 may execute a registration process to identify and select which tool, device, or object to track for distance measurements. This registration process may be initiated through the user interface 106 of the audio device 100, where a user can navigate through menu options displayed on the display 126 and use the buttons 124 to select from a list of available wireless devices detected by the sensor 152. The registration process may also include scanning for nearby wireless devices, such as mobile phones (e.g., mobile device 604), smart watches, removable tags (e.g., tag 608), or power tools (e.g., power tool 612) with wireless communication capabilities, and presenting these discovered options to the user for selection. Once a device is selected, the controller 144 may store the unique identifier or wireless signature of the selected device in the memory 148 for subsequent tracking operations.

Alternatively, the registration process may be conducted through the program application running on a user's mobile device 604 or other auxiliary device 132. The program application may provide a comprehensive user interface that displays detailed information about available devices, including device names, signal strengths, and battery levels. Through the program application, users may configure tracking preferences, set volume adjustment parameters, and establish priority settings for multi-user environments. The program application may also facilitate the pairing process between the audio device 100 and the selected tracking device, ensuring secure and reliable wireless communication.

In cases where multiple audio devices 100 are to be connected in a daisy chain configuration to form the system 141 (as further described below), the control system 140 may perform network setup procedures to establish communication links between the devices 100. The daisy chain setup process may be initiated through the user interface 106 of any audio device 100 in the intended network, where users can access network configuration menus and select options to create or join a daisy chain network. The setup process may include automatic device discovery protocols that scan for nearby compatible audio devices 100 and present them as connection options. Users may select which devices 100 to include in the daisy chain network and define the connection topology through the user interface 106 or the program application.

The daisy chain configuration may also be established through the program application, which can provide a visual representation of the network topology and allow users to drag and drop devices to create the desired connection structure. The program application may facilitate the exchange of network credentials, synchronization parameters, and volume control settings across all devices in the daisy chain. In some embodiments, the setup process may include automatic role assignment where one audio device 100 is designated as a primary controller while others function as follower devices, or the system 141 may operate in a distributed control mode where all devices 100 share control responsibilities.

The initial setup procedures may also include calibration processes where the control system 140 establishes baseline distance measurements and volume correlations. Users may be prompted to position themselves at known distances from the audio device 100 while the control system 140 records sensor readings and correlates them with user-defined volume preferences. This calibration data may be stored in the memory 148 and used to improve the accuracy of subsequent distance measurements and volume adjustments.

Referring now to step 172 of the method 170, which includes acquiring input from the sensor 152. As noted above, the sensor 152 can be any type of sensor configured to provide information to the controller 144 corresponding to a distance of a user from the audio device 100. This distance may be directly correlated to the user's position or to a position of an object associated with the user, such as the user's tool or tag.

Referring still to FIG. 9, step 174 includes determining a user distance from the audio device 100. That is, the controller 144 can process the input from the sensor 152 to determine a user distance from the audio device 100. In some instances, the controller 144 can process input from the sensor 152 to determine a user distance of a user closest to the audio device 100 e.g., when multiple users are in the area. Additionally, in some instances, the controller 144 can process input from the sensor 152 to determine a user distance to one or more speakers 104 of the audio device 100. For example, a user may be located closer to a left-side speaker than a right-side speaker. In another example, the controller 144 can process input from the sensor 152 to determine a user location in space relative to the audio device 100. The controller 144 can store this distance or location measurement (or measurements) in memory 148, such as in the data storage are of the memory 148. In some embodiments, the controller 144 can maintain a table of distances to log distance measurements to track user movement over time. In other embodiments, the controller 144 can store only a current distance measurement (e.g., a new or second distance measurement) and a previous distance measurement (e.g., an old or first distance measurement). For example, when a new distance measurement is determined, the controller 144 can store that measurement as the “current” measurement, and can consider the old current measurement as a “previous” measurement.

Step 176 includes determining whether there is a change in distance. For example, if the sensor input indicates that the user has not moved, i.e., there is no change in the distance measurement from a previous input, the controller 144 need not adjust speaker volume and the method 170 can revert back to step 172. However, if the controller 144 determines that the user has moved, i.e., the distance measurement has changed, the method 170 can proceed to step 178. In some instances, at step 176, the controller 144 can compare the current distance measurement to a previous distance measurement to determine whether the user distance has changed. Additionally, in some embodiments, step 176 may be eliminated and the method 170 can proceed from step 174 straight to step 178.

Referring still to FIG. 9, step 178 includes adjusting a speaker volume. According to one example, speaker volume may be adjusted according to a sound attenuation formula. For example, referring back to the example in FIG. 7, sound naturally diminishes over distance as follows:

$$SLP 2 = SPL 1 - 20 log ( \frac{R 2}{R 1} )$$

where SPL1 is a sound pressure level at point 1 (i.e., first user distance 162), SPL2 is a sound pressure level at point 2 (i.e., second user distance 164), R1 is the distance from the sound source 160 to point 1, and R2 is a distance from the sound source 160 to point 2. Using this sound attenuation formula, the controller 144 can determine a new volume level (SPL2) using a current volume level (SPL1), a previous user distance (R1), and a current user distance (R2). Accordingly, in some instances, the controller 144 can store user-defined volume levels in relation to user distances. For example, when a user sets or adjust the volume, or begins playing audio, after a brief waiting period (e.g., allowing a user that walked to the audio device 100 to adjust volume to walk back to their working location, such as 15 seconds, 30 seconds, 1 minute, or another suitable time period), the controller 144 can store the user-defined volume level (e.g., as SPL1) and the associated first user distance (e.g., as R1). As such, using the above equation, the controller 144 can then set a new speaker volume based on the first user distance, the user-defined speaker volume, and the second or new user distance.

According to another example, speaker volume may be adjusted using another equation that relates distance to sound pressure, such as the following:

$$New Sound Pressue = Desired Sound Pressure * Distance * Offset$$

Using this equation, the controller 144 can determine a new volume level (“new sound pressure”) using a current volume level (“desired sound pressure”), the current distance measurement (“distance”), and an offset factor (“offset”). As noted above, in some instances, the controller 144 can also store volume levels in relation to user distances. For example, when a user sets or adjust the volume, or begins playing audio, after a brief waiting period (e.g., allowing a user that walked to the audio device 100 to adjust volume to walk back to their working location), the controller 144 can use the user-defined volume level (as the new sound pressure) and the measured distance, along with a stored offset factor, to calculate and store the desired sound pressure. Then, when the user changes distance, the stored desired sound pressure, along with the new distance and the offset factor, can be used to calculate the new sound pressure value.

According to yet another example, speaker volume may be adjusted using a look-up table based on distance. For example, the look-up table may be stored in the data storage area of memory 148. According to this example, the controller 144 can use the following equation:

$$Final Sound Pressure = Lookup Table Value * Original Sound Pressure$$

Using this equation, the controller 144 can determine a new volume level (“final sound pressure”) using a base volume level (“original sound pressure”), and a lookup table value based on the current distance measurement. For example, the controller 144 can store offset values in relation to user distances as a lookup table, such as the example shown below:

| Distance (ft) | 10 | 20 | 30 | 40 | 50 | 60 | 70 |
|---|---|---|---|---|---|---|---|
| Offset Value | 2 | 4 | 8 | 16 | 32 | 64 | 128 |

For example, when a user sets or adjust the volume, or begins playing audio, after a brief waiting period (e.g., allowing a user that walked to the audio device 100 to adjust volume to walk back to their working location), the controller 144 can use the user-defined volume level (as the final sound pressure) and the measured distance along with the corresponding offset value from the lookup table, to calculate and store the original sound pressure. In some instances, the controller 144 can use the closest distance in the lookup table to the measured distance to retrieve an offset value, or can interpolate between distance points in the lookup table to calculate an offset value. Then, when the user changes distance, the stored original sound pressure, along with the new distance and corresponding offset value, can be used to calculate the new final pressure value.

Beyond the basic sound attenuation formulas disclosed, the controller 144 may implement more sophisticated volume control algorithms. In some embodiments, the control system 140 may include frequency-specific volume adjustments that modify bass, midrange, and treble levels independently based on distance, accounting for the fact that different frequency ranges attenuate at different rates over distance. The controller 144 may also incorporate ambient noise compensation that uses sensor(s) 152 (e.g., microphones) to measure background noise levels and adjust volume accordingly. In some cases, the control system 140 may include predictive volume adjustment algorithms that anticipate user movement patterns based on historical data and pre-adjust volume levels to minimize audible transitions.

Once the new speaker volume (e.g., new volume level, new sound pressure, or final sound pressure) is determined or calculated at step 178, step 180 includes controlling the speaker 104 to output audio at the new speaker volume. Additionally, in some embodiments, the controller 144 may further control the audio circuit 130 in addition to or as an alternative to the speaker 104 in order for the speaker 104 to output audio at the new speaker volume. The method 170 then cycles back to step 172 and repeats in a loop.

In light of the above method 170, the controller 144 can automatically control a volume of the audio output from the speaker 104 based on user distance. Additionally, in some instances, if the audio device 100 includes multiple speakers 104, the controller 144 can make this determination relative to the audio device 100 (e.g., for all speakers 104 generally). That is, if the user moves away from the audio device 100, the volume output of all speakers can be increased. In another example, the controller 144 can make this determination individually for each speaker 104 and individually control different volume outputs for the speakers 104. That is, the above method 170 is carried out for each speaker individually. As such, if the user moves away diagonally from the audio device 100, the controller 144 may increase the volume output of a left-side speaker more than the volume output of a right-side speaker. In yet another example, the controller 144 can make this determination relative to individual speakers collectively to accomplish a stereo sound effect. That is, if the user moves away diagonally from the audio device 100 the controller 144 may increase the volume output of a left-side speaker more than the volume output of a right-side speaker in a manner that keeps stereo sound in equilibrium. Accordingly, in these examples, the controller 144 can automatically control a volume as well as a directionality of the audio output from the speaker 104 based on user distance.

In some embodiments, the audio device 100 may communicate with centralized worksite management platforms to provide location tracking data for safety monitoring and productivity analysis. The control system 140 may include emergency broadcast capabilities that can override normal audio playback to deliver critical safety announcements or evacuation instructions. The audio device 100 may support integration with existing worksite communication systems, such as two-way radio networks or intercom systems, allowing seamless switching between entertainment audio and work-related communications based on user proximity and activity levels. The control system 140 may incorporate time-based volume scheduling that automatically adjusts audio levels during different work shifts or break periods based on worksite operational schedules.

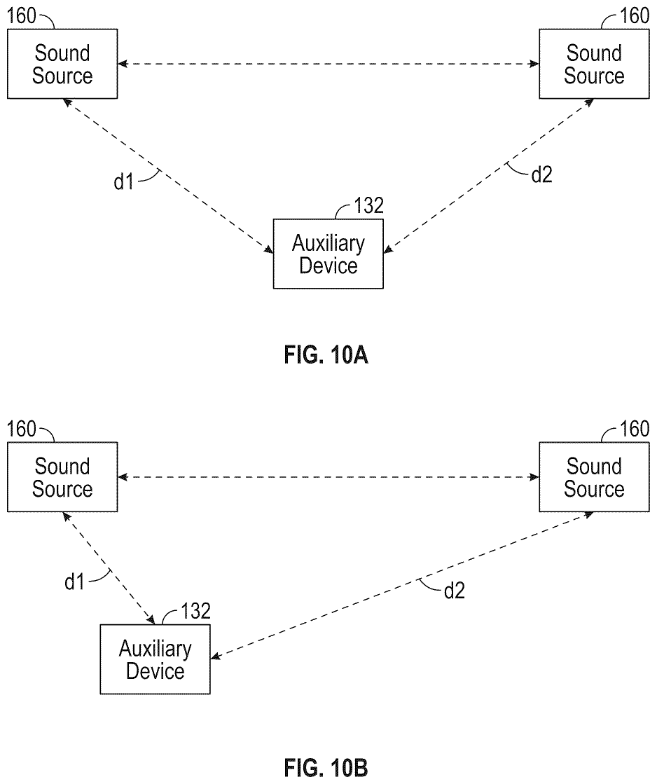

Furthermore, with reference to FIGS. 10A and 10B, in some embodiments, an audio system 141 can include multiple audio devices 100, 200, 300, 400, 500 can be daisy chained together to emit the same audio output, and the above method 170 can be applied to a set of daisy chained audio devices. This daisy chain configuration allows the creation of an expanded audio coverage area across large worksites, where individual audio devices 100 can be strategically positioned to provide optimal sound distribution while maintaining synchronized audio output. The daisy chain topology allows for scalable audio systems that can be easily reconfigured based on changing worksite layouts and requirements.

In some embodiments, the daisy-chained audio devices 100 can implement time-division multiple access (TDMA) protocols to coordinate sensor data sharing and volume adjustments across the network. The system 141 may include controller-responder hierarchies where one audio device serves as a primary controller that aggregates distance measurements from all connected devices and calculates optimal volume distributions across the entire network. The daisy-chain configuration may support dynamic reconfiguration capabilities, where audio devices 100 can be added or removed from the network without interrupting audio playback. In some cases, the system 141 may include automatic device discovery protocols that allow newly connected audio devices 100 to integrate seamlessly into existing networks and inherit current volume settings and user distance correlations.

As illustrated in FIGS. 10A and 10B, two sound sources 160 (e.g., audio devices 100, 200, 300, 400, 500) are positioned horizontally adjacent to each other and connected via a bidirectional communication link, which facilitates real-time data exchange between the connected devices, although other configurations are possible. Referring still to FIGS. 10A and 10B, the auxiliary device 132 is positioned at a first distance d1 from the left sound source 160 and a second distance d2 from the right sound source 160. As noted above, each audio device 100 can include an auxiliary interface including, for example, a wireless unit to enable wireless (e.g., Bluetooth®, Wi-Fi, or other wireless protocols) connection to an auxiliary device 132. This wireless connectivity can support various communication standards including Bluetooth Low Energy (BLE), Wi-Fi Direct, or proprietary wireless protocols optimized for worksite environments with potential interference from power tools and machinery.

Accordingly, multiple audio devices 100 can be wirelessly connected to the same auxiliary device 132, allowing for the audio devices 100 to be synced to emit the same audio output, as controlled by the auxiliary device 132. This synchronization ensures that audio playback across all connected devices maintains phase coherence and timing accuracy, preventing audio delays or echo effects that could occur in multi-device setups. The system 141 can implement advanced synchronization algorithms that account for wireless transmission delays and processing latencies to maintain audio quality across the entire network.

As noted above, in some embodiments, the auxiliary device 132 can be integrated into or connected through a battery pack 616 used in power tools 612, where the battery pack 616 includes Bluetooth® connectivity capabilities and sufficient processing power to manage multiple audio device connections simultaneously, as discussed above. This configuration allows the power tool battery to serve as both a power source and a wireless communication hub for controlling the daisy-chained audio devices 100, providing a convenient and integrated worksite solution. The battery pack integration can include dedicated wireless communication modules, antenna systems optimized for worksite environments, and power management circuits that prioritize tool operation while maintaining audio device connectivity. Additionally, the system 141 can support hierarchical control structures where one audio device 100 serves as a master controller for the daisy chain network, coordinating volume adjustments and audio synchronization across all connected devices based on collective sensor data and user proximity measurements.

In such daisy chain situations, as depicted in FIGS. 10A and 10B where the sound sources 160 are interconnected and communicate with the auxiliary device 132 at different distances d1 and d2, the controllers 144 of the daisy-chained audio devices 100 can carry out the above method 170 individually or collectively. The network configuration shown in FIGS. 10A and 10B demonstrates how the positioning of the auxiliary device 132 relative to each sound source 160 affects the communication paths and distance measurements. For example, each audio device 100 can individually carry out the above method 170 to control volume and/or directionality of their respective speaker 104 based on their individual distance measurements to the auxiliary device 132 or to users in the vicinity.

According to another example, the audio devices 100 can carry out the above method 170 collectively, where the controllers 144 communicate with each other through the daisy chain connection to coordinate volume and/or directionality adjustments across the entire system 141. This collective approach enables the overall daisy chain system 141 to achieve automatically adjustable stereo sound, where the different distances d1 and d2 shown in FIGS. 10A and 10B can be used to create balanced audio output that accounts for the spatial arrangement of the multiple sound sources 160 and the location of users or the auxiliary device 132 within the worksite environment.

For example, when the distance d2 is greater than the distance d1, indicating that the auxiliary device 132 or user is positioned farther from the right sound source 160 than from the left sound source 160, the right sound source 160 will automatically increase its volume to a greater extent than the left sound source 160. This differential volume adjustment compensates for the increased distance and ensures that the user receives balanced audio output from both sound sources 160, maintaining optimal stereo sound quality regardless of the user's position relative to the daisy-chained audio devices. The controllers 144 of the respective sound sources 160 can communicate through the daisy chain connection to coordinate these volume adjustments in real-time, with each controller 144 calculating the appropriate volume level based on its individual distance measurement to the auxiliary device 132 or user. In some embodiments, the controllers 144 can apply the sound attenuation formulas described above, such as the logarithmic formula SPL2=SPL1−20 log (R2/R1), where each sound source 160 uses its respective distance measurement as R2 and a reference distance as R1. Additionally, the controllers 144 can utilize lookup tables or linear equations to determine the appropriate volume scaling factors based on the measured distances d1 and d2. The system 141 can also account for environmental factors and ambient noise levels when determining the optimal volume adjustments, as described above, ensuring that the audio output remains clear and audible across the entire worksite area covered by the daisy-chained audio devices 100.

When multiple audio devices 100 are daisy-chained together, the system 141 may implement sensor data sharing protocols that allow devices 100 to exchange sensor readings and coordinate distance measurements across the entire network. In some embodiments, each audio device 100 may share its multi-sensor distance measurements with other devices 100 in the chain, allowing collective decision-making for volume adjustments based on comprehensive user location data. The daisy-chain network may include sensor redundancy across multiple devices 100, where sensors 152 from different audio devices can provide backup distance measurements if sensors 152 on individual devices 100 fail or become obstructed. In some cases, the network may implement distributed sensor fusion algorithms that process sensor data from multiple audio devices 100 simultaneously to generate network-wide user location maps.

In some implementations, devices or systems disclosed herein can be utilized, manufactured, or installed using methods embodying aspects of the invention. Correspondingly, any description herein of particular features, capabilities, or intended purposes of a device or system is generally intended to include disclosure of a method of using such devices for the intended purposes, a method of otherwise implementing such capabilities, a method of manufacturing relevant components of such a device or system (or the device or system as a whole), and a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of.” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

As used herein, unless otherwise defined or limited, directional terms are used for convenience of reference for discussion of particular figures or examples. For example, references to downward (or other) directions or top (or other) positions may be used to discuss aspects of a particular example or figure, but do not necessarily require similar orientation or geometry in all installations or configurations.

Also as used herein, unless otherwise limited or defined, “substantially parallel” indicates a direction that is within ±12 degrees of a reference direction (e.g., within ±6 degrees), inclusive.

Also as used herein, unless otherwise limited or defined, “substantially perpendicular” indicates a direction that is within ±12 degrees of perpendicular a reference direction (e.g., within ±6 degrees), inclusive.

Also as used herein, unless otherwise limited or defined, “integral” and derivatives thereof (e.g., “integrally”) describe elements that are manufactured as a single piece without fasteners, adhesive, or the like to secure separate components together. For example, an element stamped, cast, or otherwise molded as a single-piece component from a single piece of sheet metal or using a single mold, without rivets, screws, or adhesive to hold separately formed pieces together is an integral (and integrally formed) element. In contrast, an element formed from multiple pieces that are separately formed initially then later connected together, is not an integral (or integrally formed) element.

Additionally, unless otherwise specified or limited, the terms “about” and “approximately,” as used herein with respect to a reference value, refer to variations from the reference value of ±15% or less, inclusive of the endpoints of the range. Similarly, the term “substantially equal” (and the like) as used herein with respect to a reference value refers to variations from the reference value of less than ±10%, inclusive. Where specified, “substantially” can indicate in particular a variation in one numerical direction relative to a reference value. For example, “substantially less” than a reference value (and the like) indicates a value that is reduced from the reference value by 10% or more, and “substantially more” than a reference value (and the like) indicates a value that is increased from the reference value by 10% or more.

Also as used herein, unless otherwise limited or specified, “substantially identical” refers to two or more components or systems that are manufactured or used according to the same process and specification, with variation between the components or systems that are within the limitations of acceptable tolerances for the relevant process and specification. For example, two components can be considered to be substantially identical if the components are manufactured according to the same standardized manufacturing steps, with the same materials, and within the same acceptable dimensional tolerances (e.g., as specified for a particular process or product).

Unless otherwise specifically indicated, ordinal numbers are used herein for convenience of reference, based generally on the order in which particular components are presented in the relevant part of the disclosure. In this regard, for example, designations such as “first,” “second,” etc., generally indicate only the order in which a thus-labeled component is introduced for discussion and generally do not indicate or require a particular spatial, functional, temporal, or structural primacy or order.

The previous description of the disclosed embodiments is provided to enable any person skilled in the art to make or use the invention. Given the benefit of this disclosure, various modifications to these embodiments will be readily apparent to those skilled in the art, and the principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A method of automatically controlling speaker volume of a worksite audio device, the method comprising:
acquiring input from a sensor indicative of a distance between a power tool and the worksite audio device, wherein the power tool includes wireless communication capabilities;
determining a first user distance from a speaker of the worksite audio device based on the input from the sensor;
correlating a user-defined speaker volume with the first user distance, wherein the user-defined speaker volume is a current volume at which the speaker outputs audio as set by a user;
determining a second user distance from the speaker based on the input from the sensor as the power tool moves to a different location;
setting a new speaker volume of the audio based on the first user distance, the user-defined speaker volume, and the second user distance, wherein the power tool's location is used to calculate the appropriate volume adjustment; and
controlling the speaker to output the audio at the new speaker volume based on the power tool's current position relative to the worksite audio device.

2. The method of claim 1, wherein the sensor is a received signal strength indicator sensor that determines user distance by measuring wireless signal strength from the power tool.

3. The method of claim 1, wherein the worksite audio device includes multiple speakers, and further comprising individually controlling different volume outputs for each of the multiple speakers based on respective distances to the power tool.

4. The method of claim 1, wherein the worksite audio device is part of a daisy-chained network of multiple worksite audio devices, and further comprising coordinating volume adjustments across the multiple worksite audio devices based on respective distances to the power tool.

5. The method of claim 4, wherein coordinating volume adjustments comprises calculating differential volume levels for each worksite audio device in the daisy-chained network such that a right sound source increases its volume to a greater extent than a left sound source when the power tool is positioned farther from the right sound source than from the left sound source.

6. The method of claim 1, further comprising storing the user-defined volume level and the first user distance in memory after a waiting period allowing a user with the power tool to walk back to their working location.

7. The method of claim 1, further comprising detecting multiple power tools with wireless communication capabilities in range of the worksite audio device, wherein acquiring input from the sensor includes acquiring input indicative of the distance between a closest power tool of the multiple power tools and the worksite audio device.

8. A worksite audio device comprising:
a housing with a front side and a rear side;
a speaker disposed on the front side of the housing;
an audio circuit coupled to the speaker to provide an audio signal to the speaker, where the speaker outputs audio corresponding to the provided audio signal;
a sensor positioned along the front side of the housing and configured to acquire input indicative of distance information from a power tool with wireless communication capabilities; and
a controller in communication with the sensor, the speaker, and the audio circuit, the controller including a processor and a memory storing program instructions that, when executed by the processor, causes the controller to:
acquire input from the sensor indicative of a distance of the power tool from the speaker;
determine a first user distance from the speaker based on the input from the sensor;
correlate a user-defined speaker volume with the first user distance, where the user-defined speaker volume is a current volume at which the speaker outputs audio as set by a user;
determine a second user distance from the speaker based on the input from the sensor as the power tool moves to a different location;
set a new speaker volume of the audio based on the first user distance, the user-defined speaker volume, and the second user distance, wherein the power tool's location is used to calculate the appropriate volume adjustment; and
control the speaker to output the audio at the new speaker volume based on the power tool's current position relative to the worksite audio device.

9. The worksite audio device of claim 8, wherein the sensor is a received signal strength indicator sensor configured to determine user distance by measuring wireless signal strength from the power tool.

10. The worksite audio device of claim 8, wherein the power tool includes a battery pack with integrated wireless communication capabilities for transmitting the distance information to the sensor.

11. The worksite audio device of claim 8, further comprising multiple speakers disposed on the housing, wherein the controller is configured to individually control different volume outputs for each of the multiple speakers based on respective distances to the power tool.

12. The worksite audio device of claim 8, wherein the sensor is configured to acquire a unique identification code from the power tool.

13. The worksite audio device of claim 8, wherein the controller is to acquire the input from the sensor indicative of the distance of the power tool from the speaker via communication with a mobile device wirelessly connected to the power tool.

14. The worksite audio device of claim 8, wherein the sensor is to acquire distance information for multiple power tools, and the controller is configured to process the distance information from the closest power tool to the speaker.

15. A daisy-chained worksite audio system comprising:
multiple worksite audio devices, each worksite audio device including:
a housing;
a speaker disposed on the housing;
a sensor configured to acquire input indicative of distance information from a user; and
a controller configured to process the distance information to determine a distance between the user and the speaker;
a bidirectional communication link connecting the multiple worksite audio devices, and
wherein the controllers of the multiple worksite audio devices are configured to collectively coordinate volume adjustments of the speakers across the multiple worksite audio devices based on the respective distances to the user.

16. The daisy-chained worksite audio system of claim 15, wherein each sensor is a received signal strength indicator sensor configured to measure wireless signal strength from one of a user's mobile device, a tag comprising a Bluetooth beacon, a power tool, or a power tool battery.

17. The daisy-chained worksite audio system of claim 15, wherein the multiple worksite audio devices are wirelessly connected to a single auxiliary device, allowing the multiple worksite audio devices to be synced to emit the same audio output as controlled by the auxiliary device.

18. The daisy-chained worksite audio system of claim 15, wherein the controllers communicate with one another through the bidirectional communication link to coordinate the volume adjustments in real-time.

19. The daisy-chained worksite audio system of claim 15, wherein the sensor is configured to acquire input indicative of distance information from the user by detecting distance information to a power tool; and
wherein the power tool includes integrated wireless communication capabilities for communicating with the sensor.

20. The daisy-chained worksite audio system of claim 19, wherein the power tool is configured to transmit a unique identification code that allows the controllers to distinguish between multiple power tools.
